(19) United States
(12) Patent Application Publication
(10) Pub. No.: US 2023/0268451 A1
(43) Pub. Date: Aug. 24, 2023

(54) Cu2CdGe(S,Se)4 SOLAR CELL ABSORBERS

(71) Applicant: The Trustees of Princeton University, Princeton, NJ (US)

(72) Inventors: Emily A. CARTER, Belle Mead, NJ (US); Robert B. WEXLER, Philadelphia, PA (US); Sai Gautam GOPALAKRISHNAN, Hamilton, NJ (US)

(73) Assignee: The Trustees of Princeton University, Princeton, NJ (US)

(21) Appl. No.: 18/017,544

(22) PCT Filed: Jul. 19, 2021
(86) PCT No.: PCT/US2021/042160

§ 371 Date: Jan. 23, 2023

Related U.S. Application Data
(60) Provisional application No. 63/056,111, filed on Jul. 24, 2020.

(51) Int. Cl. H01L 31/032; C01B 19/00

(52) U.S. Cl. CPC H01L 31/0326; C01B 19/002; H01L 31/068

(57) ABSTRACT

Disclosed herein are solar cells with kesterite-based absorbers that hold promise as a low-cost and durable technology to renewably produce electricity using solar energy conversion. The current state-of-the-art (SOA) for such kesterite solar cells is Cu₂ZnSn(S,Se)₄ and novel materials are required to suppress the formation bandgap-fluctuation- and charge-carrier-recombination-inducing defects and eventually to achieve solar cell efficiencies higher than the SOA. Three important material properties that govern the efficiency of a solar cell are the concentrations of performance-degrading defects, band gap, and chemical stability. Disclosed here is a stable material, specifically Cu₂CdGe(S,Se)₄, as a new candidate that can exhibit higher defect formation energies than Cu₂ZnSnS₄ and a nearly optimal bandgap, which can eventually result in higher solar-cell efficiencies in solar energy conversion.

### CROSS-REFERENCE TO RELATED APPLICATIONS

This application claims priority to U.S. Provisional Pat. App. No. 63/056,111, filed Jul. 24, 2020, the entirety of which is incorporated by reference herein.

### STATEMENT REGARDING FEDERALLY SPONSORED RESEARCH OR DEVELOPMENT

This invention was made with government support under Grant No. DE-SC0002120 awarded by the Department of Energy. The government has certain rights in the invention.

### BACKGROUND

The potential impact of solar energy is unmistakable as it far exceeds global energy needs while simultaneously combating global warming due to its sustainability and carbon-neutrality. To capitalize on this opportunity, the scientific community has spent many decades searching for materials that efficiently convert sunlight to electricity. A number of solar-cell technologies have been commercialized, most notably those based on Si; thin-film technologies such as CdTe, Cu(In,Ga)Se₂, GaAs, and hybrid organic-inorganic halide perovskites; conductive organic polymers; and molecular dyes.

Although eco-friendly printing techniques have been used to fabricate inexpensive, nontoxic organic/polymer solar cells, solar cells with higher efficiency made of promising inorganic materials are as yet unable to supplant fossil-fuel power stations for a number of reasons, including because they contain expensive (Te, In, and Ga) and/or toxic (Cd, Pb, and As) elements and/or, in the case of perovskite solar cells, have poor resistance to moisture. Consequently, solar-energy conversion efficiency, cost, toxicity, ease of production, and stability all must be considered concurrently to design an efficient, scalable, and environmentally friendly solar infrastructure. Over the last decade, there has been growing interest in the solar absorber material Cu₂ZnSnS₄ (CZTS), which contains inexpensive and nontoxic elements, is easily synthesized, possesses ideal sunlight absorption characteristics (namely, a band gap of ≈1.39–1.52 eV), and is stable, even in the presence of moisture. Unfortunately, under processing conditions (i.e., annealing at 600 K), defects can form (e.g., antisites, vacancies, and their clusters), which leads to solar-cell inefficiencies. Therefore, materials design (e.g., composition control via ion substitution) is required to suppress during the annealing step the formation of these defects, which can induce band-gap fluctuations and charge-carrier recombination, in order to improve the overall solar cell efficiency.

### BRIEF SUMMARY

Disclosed herein is a quinary chalcogenide, namely Cu₂CdGe(S,Se)₄ (CCdGSSe), that exhibits higher defect formation energies than CZTS, which are key parameters that determine defect concentrations, the extent of band gap reduction, charge-carrier recombination rates, and the eventual solar cell efficiency. Specifically, CCdGSSe also can exhibit an optimal band gap, which can increase further the solar cell efficiency.

A first aspect of the present disclosure is a composition of matter having the formula Cu₂CdGe(SₓSe₁₋ₓ)₄, where 0 < × < 1. Ideally, 0.1 ≤ × ≤ 0.9, and more ideally, 0.7 ≤ × ≤ 0.8. The composition of matter may adopt, e.g., a stannite or wurtzite crystal structure. Optionally, the composition can be configured to have a band gap of between 1.4 eV and 1.5 eV.

A second aspect of the present disclosure is the use of the composition of matter in a solar cell. Specifically, the solar cell utilizes an absorber layer comprising a composition of matter having the formula Cu₂CdGe(SₓSe₁₋ₓ)₄, where 0 < × < 1, and preferably 0.7 ≤ × ≤ 0.8. The composition may adopt a stannite or wurtzite crystal structure.

The solar cell may be configured in a variety of ways, including, e.g., having the absorber layer sandwiched between a buffer layer and a contact layer. One example of such a configuration is where the solar cell further comprises a first contact layer (e.g., a transparent contact layer, optionally comprising a transparent conducting oxide such as SnₓIn₂₋ₓO₃) in contact with a buffer layer (e.g., a layer comprising CdS) that is in contact with a first surface of the absorber layer, as well as a second contact layer (e.g., a layer comprising Mo) in contact with a second surface of the absorber layer, the second surface being opposite the first surface. Optionally, the second contact layer is also in contact with a substrate.

### BRIEF DESCRIPTION OF THE DRAWINGS

FIG. 1A is a depiction of an exemplary crystal structure of the disclosed quinary chalcogenide adopting a kesterite crystal structure, where Cu¹⁺, Cd²⁺, Ge⁴⁺ and (S, Se)^{2–} would occupy the 1+, 2+, 4+, and 2– sites, respectively.

FIG. 1B is a depiction of an exemplary crystal structure of the disclosed quinary chalcogenide adopting a stannite crystal structure, where Cu¹⁺, Cd²⁺, Ge⁴⁺ and (S, Se)^{2–} would occupy the 1+, 2+, 4+, and 2– sites, respectively.

FIG. 1C is a depiction of an exemplary crystal structure of the disclosed quinary chalcogenide adopting a wurtzite crystal structure, where Cu¹⁺, Cd²⁺, Ge⁴⁺ and (S, Se)^{2–} would occupy the 1+, 2+, 4+, and 2– sites, respectively.

FIG. 2A is a graph showing the effect of Ge-substitution on the relative stability of the stannite and kesterite polymorphs of CZTS calculated using density functional theory (DFT) and the strongly constrained and appropriately normed (SCAN) exchange-correlation functional. f.u. is formula unit. ↑CZTGS and ↓CZTGS refer to high and low degree of Ge substitution on Sn sites of CZTS, namely Cu₂ZnSn_{0.5}Ge_{0.5}S₄ and Cu₂ZnSn_{0.9375}Ge_{0.0625}S₄.

FIG. 2B is a graph showing the effect of Ge-substitution on the DFT-SCAN neutral defect formation energies under Cu-poor conditions. Y is either Sn or Ge in ↑CZTGS and ↓CZTGS, whichever gives the lower defect formation energy; Y is Sn for CZTS; and Ge for CZGS (i.e., Cu₂ZnGeS₄). For generic A and B cations, A_{B} is an antisite (an A occupies a B site), A_{B}+B_{A} is an antisite cluster (an A occupies a B site and a B occupies an A site), and V_{A} is an A vacancy (an A site is unoccupied).

FIG. 2C is a graph showing the effect of Ge-substitution on the band gap calculated using DFT; the exchange-correlation functional of Perdew, Burke, and Ernzerhof (PBE); and Hubbard U corrections (+U). x_{Ge} is Ge/(Sn + Ge).

FIG. 3A shows an exemplary crystal structure of a kesterite polymorph of Cu₂CdGeS₃Se and, if S^{2–} (Se^{2–}) replaces all Se^{2–} (S^{2–}), CCdGS (CCdGSSe).

FIG. 3B shows an exemplary crystal structure of a stannite polymorph of Cu₂CdGeS₃Se and, if S^{2–} (Se^{2–}) replaces all Se^{2–} (S^{2–}), CCdGS (CCdGSSe).

FIG. 3C shows an exemplary crystal structure of a wurtzite polymorph of Cu₂CdGeS₃Se and, if S^{2–} (Se^{2–}) replaces all Se^{2–} (S^{2–}), CCdGS (CCdGSSe).

FIG. 4 is a graph illustrating the relative stabilities of the stannite, wurtzite, and kesterite polymorphs of CCdGS, CCdGS₃Se (CCdGSSe), and CCdGSe calculated using DFT and the hybrid exchange-correlation functional of Heyd, Scuseria, and Ernzerhof (HSE).

FIG. 5 is a graph illustrating the DFT-HSE band gap as a function of x_{Se} for 0 ≤ xsₑ ≤ 1 and polymorph (i.e., stannite and wurtzite) crystal structure in CCdGSSe.

FIG. 6 includes graphs illustrating the DFT-SCAN defect formation energies under Cu-poor conditions for stannite and wurtzite polymorphs of CCdGSSe. X is either Zn or Cd.

FIG. 7 is a graph illustrating the variation in performance among CZTS, CZGS, CZGSSe (i.e., Cu₂ZnGeS₂Se₂), and CCdGSSe where ΔE^{d}_{f} is the normalized 2Cu_{X} + Y_{X} formation energy under Cu-poor conditions, Eₕᵤₗₗ is the energy/atom above the convex hull (i.e., the energy of decomposition of a given material into the set of most stable materials at its chemical composition), and E_{g} is the normalized absolute deviation of the band gap from that of CZTS. Normalization, i.e., (y – yₘᵢₙ)/(yₘₐₓ – yₘᵢₙ), is used to bring all values of the performance indicator y into the range [0,1]. For ΔE^{d}_{f}, values of 0 and 1 correspond to the 2Cu_{Zn} + Sn_{Zn} and polymorph-averaged 2Cu_{Cd} + Ge_{Cd} formation energies under Cu-poor conditions for CZTS (0.67 eV) and CCdGSSe (1.54 eV), respectively. For Eₕᵤₗₗ, values of 0 and 1 correspond to 0.073 eV per atom (CZGSSe) and 0 eV per atom above the hull, respectively. For E_{g}, values of 0 and 1 correspond to 0.60 eV and 0 eV deviations from the DFT-HSE band gap of CZTS.

FIG. 8A shows defect formation energies under Cu-poor conditions (i.e., when CCdGS, Cd₄GeS₆, GeS₂, S, and Se are in equilibrium) of various charged vacancies, antisites, vacancy-antisite clusters, and antisite clusters considered within stannite CCdGSSe calculated using PBE+U and the D2, van der Waals correction of Grimme (+D), plotted as a function of the Fermi energy. The lines indicate the minimum defect formation energy at each Fermi energy, indicative of the most stable charged state of each defect. On the horizontal axis, 0 eV and 0.93 eV indicate the PBE+U+D-calculated valence-band maximum (VBM) and conduction-band minimum (CBM), respectively, where the zero of the Fermi energy is arbitrarily set to the VBM. For V_{Cu}, Cu_{Cd}, Cd_{Cu}, Ge_{Cd} + Cu_{Cd}, Vs + Cu_{Cd}, and V_{Se} + Cu_{Cd}, three ionized states are considered, namely, q = –1 (negatively charged, slope of –1), q = 0 (neutral, zero slope), and q = 1 (positively charged, slope of 1). For V_{S}, V_{Se}, and Ge_{Cd}, q = 2 (doubly positively charged, slope of 2) is also considered. On the vertical axis, 0 eV and 0.84 eV respectively indicate the threshold for exothermic defect formation and the PBE+U+D formation energy of the neutral 2Cu_{Zn} + Sn_{Zn} antisite cluster, which causes Shockley-Read-Hall recombination in CZTS.- The latter constitutes an upper bound on the formation energy of defects that affect solar cell parameters.

FIG. 8B is a graph of transition levels of the charged defects in FIG. 8A. The circles signify acceptor (q, 0 → –1), donor (q, +1 → 0), and donor (q, 2+ → 1+) transition levels.

FIG. 9 is a simplified diagram of a solar cell incorporating the disclosed material.

### DETAILED DESCRIPTION

Disclosed herein is a material, Cu₂CdGe(S,Se)₄ (CCdGSSe), that exhibits higher defect formation energies than Cu₂ZnSnS₄ (CZTS), which are key parameters that determine defect concentrations, the extent of band gap reduction, charge-carrier recombination rates, and the eventual solar cell efficiency. Specifically, CCdGSSe also can exhibit an optimal band gap, which can further increase the solar cell efficiency. Thus, the composition disclosed herein has the potential to increase the overall performance of kesterite solar cells.

A first aspect of the present disclosure is a composition of matter having the formula Cu₂CdGe(SₓSe₁₋ₓ)₄, where 0 < × < 1. In some embodiments, 0.05 ≤ × ≤ 0.95, 0.1 ≤ × ≤ 0.9, 0.2 ≤ × ≤ 0.9, 0.3 ≤ × ≤ 0.9, 0.4 ≤ × ≤ 0.9, 0.5 ≤ × ≤ 0.9, or 0.6 ≤ × ≤ 0.9. Preferably, 0.7 ≤ × ≤ 0.8.

Optionally, the composition is configured to have a band gap of between 1.4 eV and 1.5 eV.

Two important parameters for optimizing kesterite solar cells are the band gap (E_{g}) and the concentration of Shockley-Read-Hall (SRH) recombination centers (x_{SRH}). The band gap of the absorber, which depends on the polymorph (E^{Stannite_{g}}< E^{Kesterite_{g}}, typically), is proportional to the open-circuit voltage (V_{oc}) of the solar cell whereas x_{SRH} is a good measure of the short-circuit current (I_{sc}), with lower concentrations corresponding to higher currents. Given that efficiency is proportional to the product of V_{oc} and I_{sc}, increasing I_{sc} by decreasing x_{SRH} increases solar cell efficiency. The V_{oc}, however, cannot be increased without bound as the Shockley-Queisser limit dictates an optimal E_{g} of 1.34 eV, with quasi-exponential decline in efficiency upon deviations away from that value.

While in principle CZTS can host a wide range of neutral and charged defects including antisites, vacancies, and their clusters, the effects of the neutral defects listed in Table 1 on the physics and performance of kesterite solar cells are both significant and well-understood. Defects are labeled using a simplified Kröger-Vink notation, M_{S} (in Table 1 and thereafter), where M corresponds to the point defect species, which can be an atom (e.g., Cu) or a vacancy (V), and S indicates the lattice site that the species occupies. For Cu_{X} + X_{Cu}, Cu⁺ and X²⁺ cations swap sites. This leads to the formation of shallow donor (X_{Cu}) and acceptor (Cux) levels within the band gap, resulting in spatial fluctuations of the conduction and valence band edges. These fluctuations reduce the effective band gap, thus lowering the V_{oc} of the material. For Cu vacancies (V_{Cu}), a Cu⁺ site is unoccupied, leaving the crystal Cu-deficient. Previous quantum mechanics simulations predicted that Cu vacancies reduce potential fluctuations along the valence band edge, which can mitigate any band gap reduction caused by Cu_{X} + X_{Cu} clusters. Consequently, V_{Cu} tends to mitigate any reduction in V_{oc}, consistent with the Cu-poor synthesis conditions that typically are employed to achieve highest efficiency. Finally, for 2Cu_{X} + Y_{X}, three X²⁺ are replaced by two Cu⁺ and one Y⁴⁺, leaving the crystal X²⁺-deficient and Cu⁺/Y⁴⁺-rich. Previous quantum mechanics studies indicate that 2Cu_{Zn} + Sn_{Zn} generates localized trap states near the center of the band gap, which promote SRH recombination and, therefore, reduce the I_{sc} of CZTS. It is noted that interface recombination also can reduce the V_{oc}, however, the goal of the disclosed materials was to suppress the formation of bulk defects that are well-known, via both experiment and theory, to be detrimental to kesterite solar cell efficiency.

Table 1. Defects considered and their effects on the physics of kesterite solar cells and solar cell parameters. X is Zn, Cd, or Mg; Y is Sn, Ge, or Si; E_{g} is the band gap; V_{oc} is the open-circuit voltage; and I_{sc} is the short-circuit current.

| | | |
|---|---|---|
| Defect | Effect on the physics of kesterite solar cells | Primary effect on solar cell parameters |
| Cu_{X} + X_{Cu} | Causes electrostatic potential fluctuations | Decreases V_{oc} |
| V_{Cu} | Mitigates potential fluctuations along valence band edge | Increases V_{oc} |
| 2Cu_{X} + Y_{X} | Causes Shockley-Read-Hall recombination | Decreases I_{sc} |

Density functional theory (DFT) and thermodynamic analyses have been employed to improve fundamental understanding of how to control defect formation and to identify promising doping schemes to limit the formation of detrimental defects and improve solar cell performance. For example, theory and experiment both conclude that Ag-containing phases are more ordered in the 1+ and Zn²⁺ sublattices (i.e., lower concentration of Cu_{X} + X_{Cu} defects) due to the anisotropic expansion of the unit cell upon replacement of Cu by Ag. Specifically, Ag₂ZnSnSe₄ affords a higher predicted maximum photovoltaic efficiency than Cu₂ZnSnS₄, consistent with experiments. The alkali metals are another promising group of isovalent replacements for Cu, with theory indicating that <25% Na-doping in CZTS suppresses the formation of Cu_{Zn} + Zn_{Cu}. In addition to the Cu⁺ site, several studies establish isovalent doping on the Zn²⁺ site as a promising strategy to improve the performance of CZTS-based solar cells as well. Among the 2+ cations considered, which includes the alkaline earth and transition metals, Cd has been identified, by both theory and experiment, as one of the most effective at reducing 1+/2+ and 2+/4+ cation disorder. Finally, on the 4+ site, Ge stands out as an exceptional candidate for substitution, as numerous studies, mostly experimental, have shown that the combination of partial Ge- and Se-alloying, where the latter serves primarily to optimize the band gap, leads to significant increases in both the V_{oc} and I_{sc} and thus solar-cell efficiency. However, there remains scarce mechanistic understanding of these dopants’ influence on defect formation and consequently uncertainty regarding promising directions for improved materials design.

To address this need, predictions of bulk stability, band gap, and formation energies for the key defects are presented in Table 1.

Since CZTS offers a nearly optimal band gap (≈1.5 eV), one would like post-CZTS absorbers to simply lower x_{SRH} without significantly changing the band gap. First, it is found that Mg- and Si-substitution for Zn and Sn, respectively, increases E_{g} and, for Mg-substitution, increases x_{SRH} as well, which will lead to inefficient solar cells. Therefore, Mg and Si are not considered further. Second, it is found that complete Ge-substitution (CZGS) decreases x_{SRH} but increases E_{g}. While partial Ge-substitution (CZTGS) increases E_{g} by a lesser extent, it is found that this approach is not as promising as partial selenization (CZGSSe). Third, it is found that complete Cd-substitution, along with Ge-substitution coupled with partial selenization, provides the optimal band gap and significantly decreases x_{SRH}, thus identifying CCdGSSe as a promising candidate for improving the efficiencies of kesterite-based solar cells. By discussing these steps, both the independent and concerted effects of Ge, Se, and Cd on defect thermodynamics and electronic structure are revealed, leading to an optimized composition for kesterite solar cell absorbers, i.e., CCdGSSe.

### Computational Methods

All calculations in this work were performed with spin-polarized density functional theory (DFT), as implemented in the Vienna Ab Initio Simulation Package, and employing projector augmented-wave potentials. We used a kinetic energy cutoff of 520 eV, sampled a minimum of 32 k-points per Å^{–1}, and used a convergence threshold of 0.01 meV and |0.03| eV/Å on total energies and atomic forces, respectively. We used the strongly constrained and appropriately normed (SCAN) functional for all structural relaxations, Heyd-Scuseria-Ernzerhof (HSE) hybrid functional for band gap calculations in CCdGSSe, and the Hubbard-U-corrected Perdew-Burke-Erznerhof (PBE+U) functional for charged defect calculations. U values used in PBE+U were 3.6, 4.5, and 4.8 eV for Cu 3d, Zn 3d, and Ge/Sn 3d/4d orbitals, respectively. For bulk structures, we relaxed the cell shape, size, and ionic positions while for all defective structures (initialized in 2×2×2 supercells of the bulk), we only relaxed ionic positions.

The convergence of bulk thermodynamic quantities with respect to the kinetic energy cutoff, k-point grid density, and the inclusion of semicore states in the PBE PAW data sets for Cu and Ge are known.

Charged defect calculations using the PBE+U+D functional were performed instead of SCAN because the latter grossly underestimates the band gaps of CZTS and CZGS.

### Structural Models

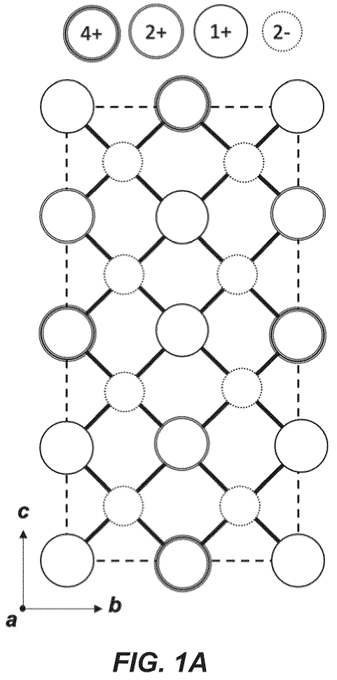

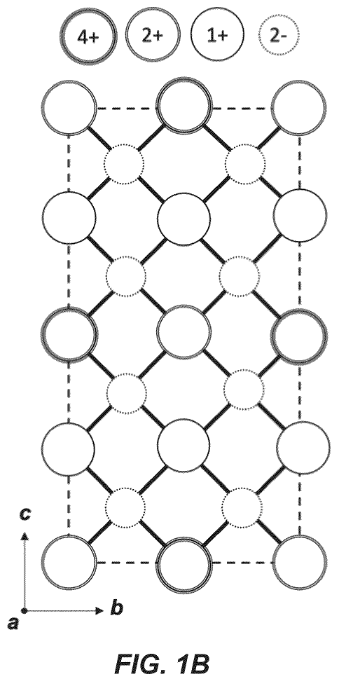

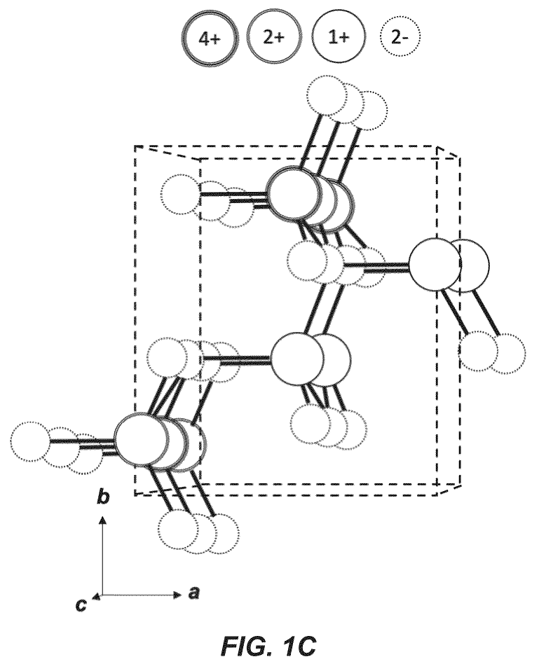

Prior to defect formation energy calculations, the lowest energy crystal structure of the defect-free material was determined. CZTS-like quaternary chalcogenides typically exist in one of three polymorphs: kesterite, stannite, and wurtzite-stannite (which, for simplicity, will be referred to herein as wurtzite), which are displayed in FIG. 1A (kesterite), 1B (stannite) and 1C (wurtzite). In some preferred embodiments, the composition of matter may optionally adopt either a stannite or a wurtzite polymorph or a fully disordered structure.

All three polymorphs comprise corner-sharing tetrahedrons of four-fold anion-coordinated 1+, 2+, and 4+ cations. The kesterite and stannite polymorphs have similar space groups (I4̅ and I4̅2m, respectively) but differ in terms of their cation layer composition along the c lattice vector, where kesterite has alternating 1+/2+ and 1+/4+ layers and stannite has alternating 1+ and 2+/4+ layers. The main difference between wurtzite (space group: P6₃mc) and kesterite/stannite is the underlying S-arrangement.

For (partial) ion-substituted quinary chalcogenides, the lowest energy ionic configuration was also determined. In the case of Ge-substituted CZTS, both the kesterite and stannite polymorphs and two concentrations of Ge were considered: dilute (x_{Ge} = Ge/(Sn + Ge) = 0.0625) and high (x_{Ge} = 0.5). For dilute Ge, which can be referred to as ↓CZTGS, there is only one possible symmetry-unique Sn/Ge configuration within a 2 × 2 × 2 supercell, i.e., Ge in the Cu/Sn layer of kesterite and the Zn/Sn layer of stannite. Note that, to calculate defect formation energies at infinite Ge dilution, the cell was fixed to that of relaxed CZTS. For all other bulk structures considered, the lattice vectors and ions were relaxed. For high Ge-substitution, which is referred to as ↑CZTGS, the cell was optimized and, to reduce the number of Sn/Ge configurations, the one possible symmetry-unique Sn/Ge configuration in the 16-atom conventional cell was used.

For Se-substituted CZGS (i.e., CZGSSe), all symmetry-unique S/Se configurations for x_{Se}= Se/(S + Se) = 0.5 in the 16-atom conventional cell of kesterite and stannite CZGS were used. Pymatgen’s structure matcher was used, which is powered by spglib, to generate the symmetry-unique configurations of which there are 12 for kesterite and 10 for stannite. Finally, for CCdGSSe, in the same way as for CZGSSe, all symmetry-unique S/Se configurations for x_{Se}= 0.25 in kesterite (there are five), stannite (five), and wurtzite (11) were considered. The wurtzite polymorph for CCdGSSe was included because it is observed experimentally for CCdGS and CCdGSe and it is nearly isoenergetic with stannite. Wurtzite is not relevant, however, for the quaternary chalcogenides containing Zn (CZTS, CZGS, CZTSe, or CZGSe) because it is less stable than the kesterite (ground state) and stannite (metastable) phases.

All defects were generated in 2 × 2 × 2 supercells of their defect-free, bulk kesterite, stannite, or wurtzite structures using the protocol described below.

### Computational Materials Design Protocol

The objective of this study was to identify strategies, specifically those involving ion substitution, for the suppression of Cu_{X} + X_{Cu} and 2Cu_{X} + Y_{X} and the promotion of V_{Cu}. Y as used herein refers to either Ge or Sn and does not refer to the element Yttrium. To this end, the study primarily focused on ion substitution at the 2+ and 4+ sites as these are directly involved in the defects to be suppressed and have not yet been studied exhaustively. The study considered Zn, Mg, and Cd at the 2+ site; Sn, Ge, and Si at the 4+ site; and S and Se at the 2– site. These selections were the result of discarding elements that are radioactive, rare (Ru, Rh, Te, Re, Os, Ir, Pt, Au, Bi), redox-active (Ti, V, Cr, Mn, Fe, Co, Ni), possess the wrong oxidation state (i.e., not 2+, 4+, or 2–), or too small/large in terms of their ionic radius (e.g., <30% or >170% compared to the ionic radius of four-fold-coordinated Cu¹⁺, Zn²⁺, Sn⁴⁺, and S^{2–}corresponding to the occupation of 1+, 2+, 4+, and 2– sites, respectively).

Redox-active elements were not considered because they can promote defect formation, e.g., Mn can occupy both the 2+ and 4+ sites thereby promoting 2+/4+ disorder. Li⁺ and Zr⁴⁺ were not considered because Li₂ZnSnS₄ and Cu₂ZnZrSe₄ are wide-band-gap semiconductors (2.87 eV and 1.95 eV, respectively); Ag⁺, Na⁺, and Ti⁴⁺ were not considered because Ag- and Na-substituted CZTS, and Cu₂ZnTi(S,Se)₄ already were studied computationally and experimentally and their behavior known; and Hf⁴⁺ because there is scarce experimental evidence of Hf forming quaternary chalcogenides (such as Cu₂ZnHf(S/Se)₄). Toxic elements (Be, Cd, Hg, Pb) were considered because toxicity can be mitigated through the practice of thoughtful device engineering. For example, previous efforts have successfully devised encapsulation schemes to ensure that CdTe solar cells, which contain more Cd by mass (47 wt%) than CCdGSSe (23 wt%), are significantly less toxic than they ought to be. Hence, it is expected that similar encapsulation and water-proofing schemes will be useful for large-scale deployment. In contrast to toxicity, abundance, oxidation state, and ionic radius are, to a large extent, immutable characteristics and the effects of radioactivity are difficult to contain.

To determine the chemical potentials at which the quaternary chalcogenides (CZTS, CZGS, CZGSe, CCdGS, and CCdGSe) are in equilibrium with different combinations of secondary phases containing their constituent ions, 0 K phase diagrams were constructed using pymatgen, which takes as inputs the DFT-SCAN (or DFT-HSE for CCdGSSe) total energies of all sub-quinary compounds and elements. Bulk structures for elements, binaries, ternaries, and quaternaries containing Cu, Zn, Mg, Cd, Sn, Ge, Si, S, and Se were taken from the inorganic crystal structure database. These structures were relaxed with DFT-SCAN and the same PAW potentials, kinetic energy cutoff, and k-point sampling density as above were used. Previous work has shown that DFT-SCAN systematically underestimates the formation energies of Ge-containing compounds by 0.27 eV/Ge. Therefore, 0.27 eV/Ge is subtracted from all DFT-SCAN formation energies of Ge-containing compounds.

In the screening part of this study, only neutral defects were considered, meaning that atoms are removed from or added to the structure in their neutral elemental form. Once an optimal composition was identified, charged defects for that composition were then considered and characterized.

Neutral defect formation energies were calculated as:

$$\text{Δ} {E}_{f}^{d} = {E}_{d}^{S C A N} - {E}_{b}^{S C A N} + {\sum }_{i} {n}_{i} {μ}_{i} \qquad \text{(1)}$$

where d is the defect supercell, b is the bulk supercell, n is the number of neutral atoms removed from (n > 0) or added to (n < 0) the system to form defect d, i is an index that runs over the unique species in the compound, and µ is the corresponding chemical potential. When point defects are created, the atoms that contribute to forming such defects must be exchanged with an external reservoir. Experimentally, this external reservoir may be ambient atmosphere during annealing, the current collecting phases that are in contact, or a secondary phase, such as leftover binary phases (e.g., CdS) that were used for the actual synthesis of the chalcogenide absorber. While theoretically we can calculate the formation energies of various isolated defects and defect complexes over a range of thermodynamically possible chemical potentials, the specific experimental conditions will precisely define the formation energy of a given defect. Here, we adopt the Cu-poor experimental conditions, with the phases that coexist with the quaternary/quinary chalcogenide determined by the 0 K phase diagram (i.e., convex hull) of the overall quaternary/quinary system. We selected Cu-poor chemical potential limits for CZGSSe and CCdGSSe because CZTS and CCdTS synthesized under this condition achieve high efficiency. For example, under Cu-poor conditions, CZTS is in equilibrium with ZnS, SnS₂, and S; CZGS is in equilibrium with ZnS, GeS₂, and S; and CZGSe is in equilibrium with ZnSe, GeSe₂, and Se. CZTGS, CZGSSe, and CCdGSSe are metastable compounds at 0 K with the equilibrium compounds at their compositions being CZTS, CZGS, ZnS, SnS₂, and S; CZGS, ZnS, GeS₂, S, and Se; and CCdGS, Cd₄GeS₆, GeS₂, S, and Se, respectively. For metastable compounds, the chemical potentials determined by the stable compounds were used. The effect of temperature on the variation of chemical potentials was not considered in these calculations but this effect is expected to be small between 0 K and 298 K.

For completeness, the following charged defects and defect clusters were considered to examine the possible role of defect transition levels in our newly proposed CCdGSSe: Cu_{Cd} (q = –1, 0, 1), Cd_{Cu} (q = –1, 0, 1), Ge_{Cd} (q = –1, 0, 1, 2), V_{Cu} (q = –1, 0, 1), V_{S} (q = –1, 0, 1, 2), V_{Se} (q = –1, 0, 1, 2), V_{S} + Cu_{Cd} (q = –1, 0, 1), V_{Se} + Cu_{Cd} (q = –1, 0, 1), and Ge_{Cd} + Cu_{Cd} (q = –1, 0, 1). Charged defect (cd) formation energies were calculated as

$$\text{Δ} {E}_{f}^{c d} = {E}_{f}^{d} + q {E}_{F} + {E}_{c} ,$$

where E_{F} is the Fermi energy of the pristine bulk structure and E_{c} is the electrostatic correction term, calculated using the correction scheme of Kumagai and Oba as implemented in the Spinney package. The PBE+U dielectric tensor of CCdGSSe used in the charge defect calculations is:εₓₓ = ε_{yy} = 10.5; ε_{zz} = 9.97; ε_{xy} = ε_{yz} = –0.06; and ε_{zx} = 0.6.

### Computational Discovery of CCdGSSe

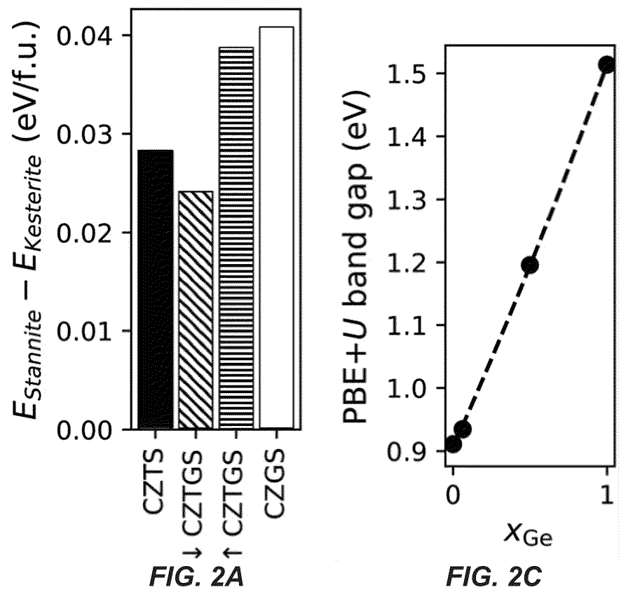

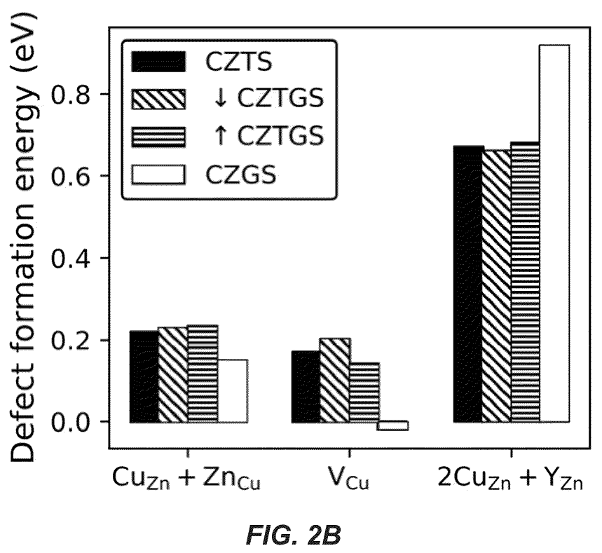

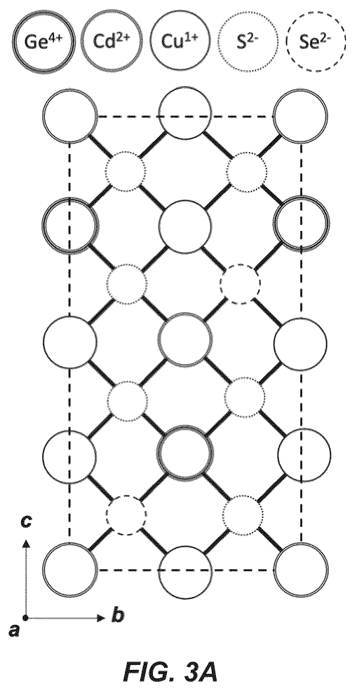

Given the deep-trap-inducing nature of 2Cu_{Zn} + Sn_{Zn} antisite clusters in CZTS and the primary role played by the Sn_{Zn} antisite, the replacement of Sn⁴⁺ with varying amounts of Ge⁴⁺ was first explored. FIGS. 2A-2C shows the effect of dilute (diagonal slashes), high (horizontal lines), and complete (white) Ge-substitution in CZTS (black) on kesterite vs. stannite polymorph preference (FIG. 2A), neutral defect formation energies under experimentally relevant Cu-poor conditions (FIG. 2B), and the PBE+U band gap (FIG. 2C).

The results show that Ge-substitution does not affect polymorph preference (FIG. 2A) with kesterite being the ground-state polymorph (E_{Stannite} – E_{Kesterite} > 0 eV per formula unit) for all x_{Ge}. That Ge increases the relative stability of kesterite vs. stannite for all but dilute Ge-substitution is in general agreement with other theoretical work and the experimental observation of enhanced grain growth in Ge-doped CZTSSe. Recent scanning electron microscope images show that grain growth and crystallinity in CZTGS is not improved for x_{Ge} > 0.2 but this could be due to suboptimal annealing conditions for each Ge composition during fabrication. Accordingly, non-dilute Ge-substitution should favor kesterite formation and suppress E_{g}/V_{oc} lowering due to the kesterite → stannite phase transition.

Trends in defect formation energies were analyzed as a function of x_{Ge} (FIG. 2B). For the Cu_{Zn} + Zn_{Cu} antisite clusters, it was found that, while partial Ge-substitution does not influence their formation (0.22 eV for CZTS and ~0.23 eV for both ↓CZTGS and ↑CZTGS), complete substitution has a promoting effect (0.15 eV for CZGS), which can be explained by the greater covalency of Ge—S bonds (ΔEN = 0.57, where EN is the Pauling electronegativity) compared to Sn—S bonds (ΔEN = 0.62). Ge—S bond covalency, which is greatest for complete Ge-substitution, reduces the charge density on S and promotes covalency across the Cu—S and Zn—S bonds. In turn, higher covalency reduces the effective 1+ and 2+ charges on the Cu and Zn, respectively, and consequently, the electrostatic energy penalty for Cu_{Zn} + Zn_{Cu} disorder. Therefore, CZGS should be more susceptible to Cu/Zn-disorder-induced potential fluctuations, and potential V_{oc} deficit. Several studies found that partial Ge-substitution in CZTSSe increases the V_{oc}, however, it is emphasized that these materials are selenized and selenization suppresses stannite and promotes V_{Cu} in CZGS.

For Cu vacancies, with the exception of ↓CZTGS (0.20 eV), it was predicted that Ge-substitution decreases their formation energy (0.17 eV for CZTS, 0.14 eV for ↑CZTGS, and –0.02 eV for CZGS) to the extent that DFT-SCAN predicts a nonzero equilibrium concentration of V_{Cu} in CZGS at 0 K. In all likelihood, this negative value for V_{Cu} in CZGS is an artifact of DFT-SCAN’s tendency to produce lower values of ΔE^{d}_{f} compared to DFT-PBE, PBE+U, SCAN+U, and DFT-HSE. For example, compared to DFT-HSE, DFT-SCAN predicts the ΔE^{d}_{f} for V_{Cu} to be lower by 0.53 eV in CZTS and 0.58 eV in CZGS. Importantly, we previously showed that qualitative trends in ΔE^{d}_{f} are XC-functional-insensitive and therefore one can simply interpret this negative value as “high to complete Ge-substitution promotes V_{Cu} formation”.

The decrease in the V_{Cu} formation energy upon complete replacement of Sn with Ge can be rationalized as follows. The Ge—S 298 K neutral diatomic bond dissociation enthalpy (BDE = 5.54 ± 0.03 eV) is substantially larger than that of Sn—S (4.84 eV) and, by replacing Sn—S bonds with stronger Ge—S bonds, Ge-substitution effectively weakens Cu—S bonds. As a result, less energy is required for Cu to break its bonds with S and form vacancies. In terms of solar cell parameters, the low ΔE^{d}_{f} for V_{Cu} in CZGS should mitigate the V_{oc}-lowering effects associated with complete Ge-substitution.

Finally, for 2Cu_{Zn} + Y_{Zn} antisite clusters, where Y is either Sn or Ge, it is clear that complete Ge-substitution strongly suppresses their formation (0.92 eV) compared to CZTS (0.67 eV), ↓CZTGS (0.66 eV), and ↑CZTGS (0.68 eV). The difference between CZTS and CZGS (0.25 eV) can be attributed to the inert pair effect, which stabilizes the 2+ oxidation state of Sn and, therefore, stabilizes Sn on the Zn²⁺ site by reducing it from 4+ to 2+. Ge, on the other hand, only exists stably in a 4+ oxidation state, as evidenced by the positive ΔG₂₉₈ for the reduction of GeS₂ to GeS (0.80 eV), i.e., Ge(IV)S₂ → Ge(II)S + S. Furthermore, Ge-substitution suppresses 2Cu_{Zn} + Y_{Zn} only under complete substitution because Ge does not affect the 2Cu_{Zn} + Sn_{Zn} formation energies and these defect clusters will continue to form as long as Sn, which is susceptible to reduction via the inert pair effect, is present in the structure. Hence, unless the more redox active Sn is completely replaced by the less redox active Ge, the ΔE^{d}_{f} for 2Cu_{Zn} + Y_{Zn} should remain close to that for CZTS. With that being said, partial Ge-substitution still can suppress the formation of 2Cu_{Zn} + Y_{Zn} by reducing x_{Sn}, thus shedding light on the experimentally observed increase in minority charge carrier lifetimes for Ge-alloyed (x_{Ge} = 0.3) CZTSSe.

### Effect of Selenization on CZGS

One way to reduce the band gap of CZGS is Se-substitution (also known as selenization); this has been used extensively to reduce/optimize the band gap of CZTS. Band gap reduction in both CZTS and CZGS upon selenization can be explained by the slightly lower electronegativity of Se (2.55 on the Pauling scale) compared to S (2.58), which pushes the valence band edge (comprising mostly Cu 3d and anion p states) up in energy but does not affect the conduction band edge (mostly Sn 5s). As a result, the band gap shrinks and the extent to which it does depends on x_{Se}= Se/(S + Se). The crystal structure of the lowest energy S/Se configuration of kesterite CZGSSe is composed of alternating S and Se (011) planes. As expected, the results show that selenization decreases E^{PBE+U}_{g} from 1.51 eV (CZGS) to 0.59 eV (CZGSe), with the magnitude of the decrease in excellent agreement with the experimental and theoretical literature. Additionally, it is found that the PBE+U band gap of CZGSSe (0.92 eV) is approximately equal to the optimal CZTS value (0.91 eV). With respect to polymorph preference, the introduction of 50% Se (CZGSSe) marginally stabilizes the low-E_{g} stannite polymorph relative to CZGS but not with respect to CZTS, thus signaling that selenization should not exacerbate polymorphism-derived V_{oc} deficits.

In view of the favorable band gap and stability of kesterite CZGSSe, the dependence of defect formation energies on x_{Se} was investigated. First, it is found, as do powder neutron diffraction measurements, that selenization slightly suppresses the formation of V_{oc}-reducing Cu_{Zn} + Zn_{Cu} antisite clusters relative to CZGS (0.15 eV for CZGS versus 0.20 and 0.16 eV for CZGSSe and CZGSe, respectively; CZTS is 0.22 eV). Furthermore, it is predicted that selenization promotes E_{g}-increasing/V_{oc}-restoring Cu vacancies (–0.02 eV for CZGS versus –0.12 and –0.09 eV for CZGSSe and CZGSe, respectively), due to the decrease in bond strength from Cu—S (BDE = 2.85 ± 0.15 eV) to Cu—Se (2.64 ± 0.15 eV) and the endoergicity of Cu₂S + Se → Cu₂Se + S (ΔG₂₉₈ = 0.12 eV). In spite of these promising trends, selenization counteracts the Ge-induced suppression of I_{sc}-lowering 2Cu_{Zn} + Ge_{Zn} antisite clusters (0.92 eV for CZGS > 0.77 eV for CZGSSe > 0.69 eV for CZGSe ≈ 0.67 eV for CZTS, black dotted line). This phenomenon is ascribed to the following mechanism. While 2Cu_{Zn} + Ge_{Zn} is charge-balanced, the balancing charges (two holes and two electrons from 2Cu_{Zn} and Ge_{Zn}, respectively) are slightly delocalized. Therefore, it is reasonable to expect that the stability of 2Cu_{Zn} + Ge_{Zn} depends, to some extent, on the anion’s tolerance for delocalization. Since Se is less electronegative (and more polarizable) than S, it should be able to accommodate more delocalization and, therefore, stabilize 2Cu_{Zn} + Ge_{Zn}. Thus, selenization of CZGS should decrease I_{sc}, counteracting the beneficial suppression of Cu_{Zn} + Zn_{Cu} and promotion of V_{Cu}. A final ion substitution step therefore must be taken in order to minimize the need for E_{g}-remediating but I_{sc}-decreasing selenization in CZGS.

### Cooperative Effect of Cd-Substitution and Selenization on CZGS

Previously, it was predicted and subsequently observed that replacing the Zn in CZTS with Cd, under Cu-poor conditions, decreases its band gap and suppresses the formation of the deep-trap-level-inducing 2Cu_{X} + Sn_{X}, where X is either Zn or Cd. For these reasons, Cd-substitution in CZGS should limit the extent to which selenization is necessary and further suppress the formation of I_{sc}-lowering defects. To test this hypothesis, complete Cd-substitution was considered in CZGS, leading to CCdGS, and with 25% and 100% selenization, where the former was chosen as an intermediate Se-substitution condition by interpolating between the DFT-HSE band gaps of CCdGS and CCdGSe to find the value of x_{Se} for which E^{HSE}_{g}[CCdGSSe] ≈ E^{HSE}_{g}[CZTS] = 1.49 eV.

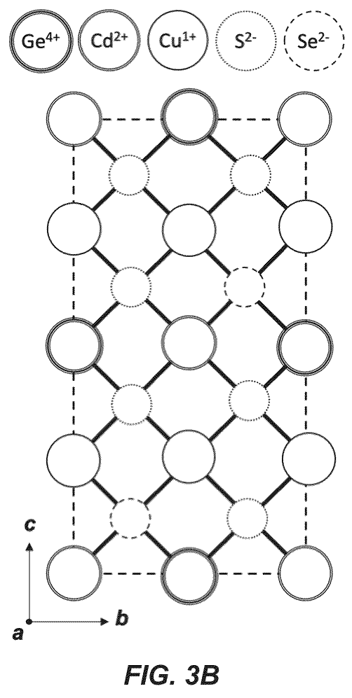

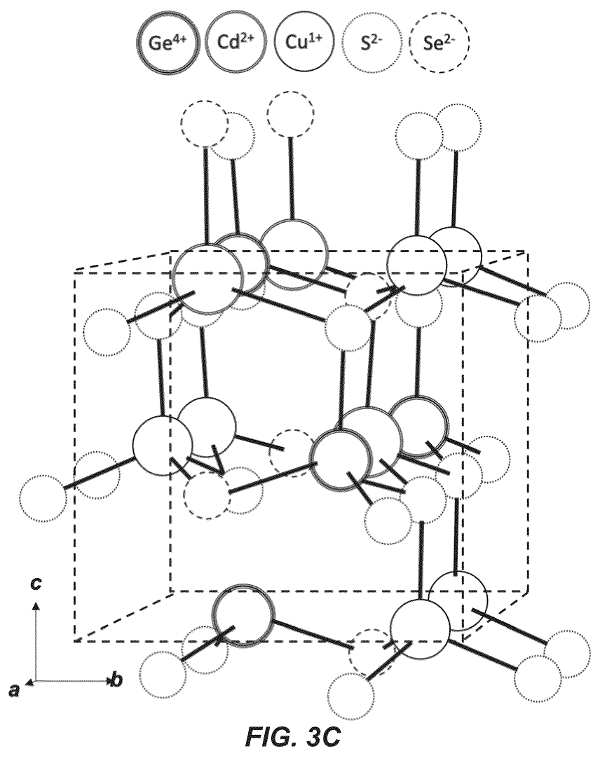

FIG. 3A shows an example of one of the ionic configurations of kesterite CCdGSSe.

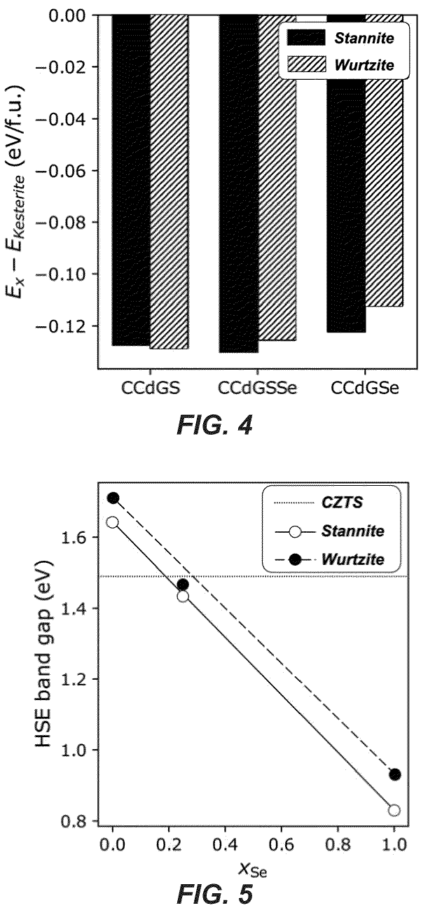

FIGS. 3B and 3C show the ground state S/Se configuration in stannite and wurtzite CCdGSSe, respectively. Both of these polymorphs were examined because they are nearly isoenergetic (See FIG. 4) and more stable than kesterite (Eₛₜₐₙₙᵢₜₑ – E_{Kesterite} < 0 and E_{wurtzite} – E_{Kesterite} < 0). Fortunately, the DFT-HSE band gaps of stannite and wurtzite CCdGSSe are similar in terms of their dependence on x_{Se} (FIG. 5) and achieve optimality at ≈25% selenization (1.43 and 1.47 eV for stannite and wurtzite, respectively), which suggests that, despite the polymorphism that is likely present in real samples, the energy offset between bands at stannite-wurtzite interfaces and, therefore, interfacial recombination rates should be small. However, as is seen in FIG. 5, the band gap can be modified by, e.g., adjusting x_{Se}.

Furthermore, optimality at x_{Se} = 0.25 indicates that complete Cd-substitution cuts the need for Se-substitution in half, compared to CZGS → CZGSSe.

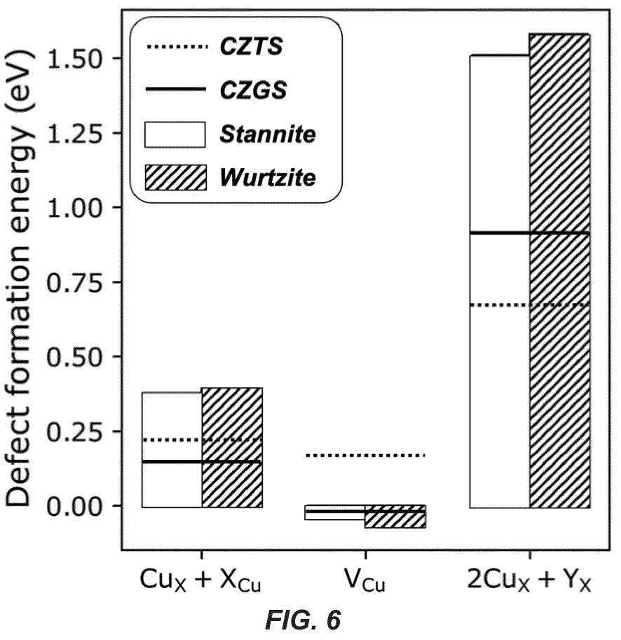

Perhaps the most dramatic effect of Cd-substitution is on the defect thermodynamics of CZG(S,Se). FIG. 6 reveals that Cd-substitution suppresses the formation of V_{oc}-lowering Cu_{Cd} + Cd_{Cu} antisite clusters in CCdGSSe (0.38 eV and 0.39 eV for stannite and wurtzite, respectively) compared to Cu_{Zn} + Zn_{Cu} in CZTS (blue dotted line at 0.22 eV) and more than doubles the Cu_{Zn} + Zn_{Cu} ΔE^{d}f in CZGS (blue solid line at 0.15 eV). The suppression of Cu_{X} + X_{Cu} can be attributed to the larger ionic radius of Cd²⁺ compared to Cu⁺ and Zn²⁺. Additionally, Cd-substitution promotes the formation of V_{oc}-increasing Cu vacancies (–0.04 eV and –0.07 eV for stannite and wurtzite, respectively) compared to CZTS (0.17 eV), while the ΔE^{d}_{f} for V_{Cu} in CCdGSSe is quite similar to CZGS (–0.02 eV). Thus, the stronger Ge—S bonds (versus Sn—S bonds) primarily govern the ease of formation of V_{Cu} in Ge-containing quaternary/quinary chalcogenides. Most importantly, Cd-substitution leads to a remarkably strong suppression of 2Cu_{Cd} + Ge_{Cd} in CCdGSSe (1.51 and 1.58 eV in stannite and wurtzite, respectively) relative to CZTS (0.67 eV) and CZGS (0.92 eV). The much higher

$$\text{Δ} {E}_{f}^{d}$$

corresponds to a roughly seven orders of magnitude decrease in x_{SRH} under CZTS annealing conditions (600 K), i.e., the maximum temperature to which CZTS is heated during synthesis, thus constituting an upper bound for crystalline defect concentrations.

The decrease (z) in the concentration of 2Cu_{X}+Y_{X} SRH recombination centers in CZGS upon Cd— and Se-substitution is roughly given by

$$z = \frac{exp \left(- \text{Δ} {E}_{f}^{d} \left[C C d G S S e\right] / {k}_{B} T\right)}{exp \left(- \text{Δ} {E}_{f}^{d} \left[C Z T S\right] / {k}_{B} T\right)} ,$$

where

$$\text{Δ} {E}_{f}^{d} [ C C d G S S e ] = \text{1} \text{.51 eV}$$

is the formation energy of 2Cu_{Cd}+Ge_{Cd} in CCdGSSe,

$$\text{Δ} {E}_{f}^{d} \left[C Z T S\right] = 0.67$$

eV is the formation energy of 2Cu_{Zn}+Sn_{Zn} in CZTS, k_{B} is the Boltzmann constant, and T = 600 K is the temperature typically employed during selenization. Inserting these values into that equation, one obtains z=8.8 × 10⁻⁸.

The significant suppression of 2Cu_{Cd} + Ge_{Cd} can be attributed to the large ionic radius difference between Cd²⁺ (0.78 Å in tetrahedral coordination) and Ge⁴⁺ (0.39 Å). Note that the local anionic configuration of CCdGSSe does not significantly affect its defect formation energies, which have a standard deviation of 0.06 eV.

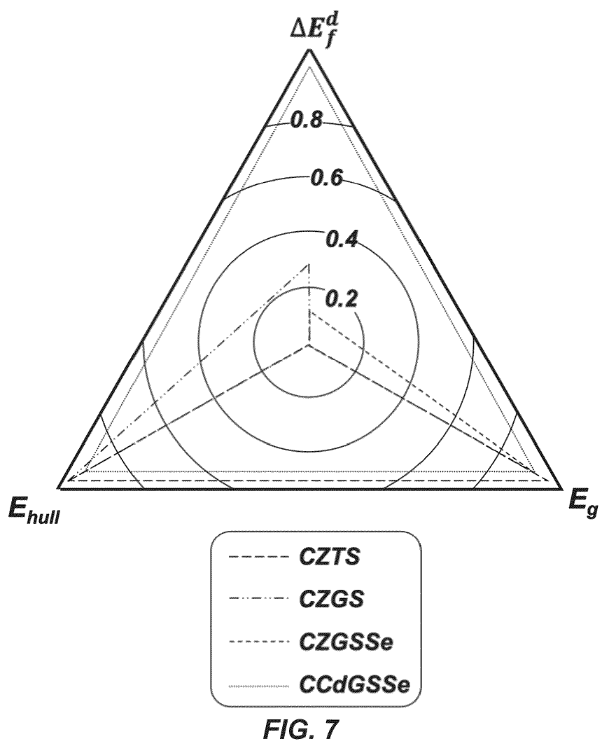

Having discussed Ge-, Se-, and Cd-substitution individually (in order to reveal their independent effects on defect thermodynamics and electronic structure), FIG. 7 now compares the performance of CZTS (long dashed line), CZGS (double dotted dashed line), CZGSSe (short dashed line), and CCdGSSe (dotted line). The origin, i.e., (0,0,0), is the center of the triangle and the axes, i.e., the closed line segments bounded by the origin and the vertices of the black triangle, correspond to the intrinsic stability/instability (energy above the convex hull at 0 K, Eₕᵤₗₗ), the band gap (E_{g}), and the formation energy of deep-trap inducing 2Cu_{X} + Y_{X} defect clusters

$$\left(\text{Δ} {E}^{\text{d}} {}_{\text{f}}\right) ,$$

which directly relate to the synthesizability, V_{oc}, and I_{sc}, respectively. Each axis is normalized as: (1)

$$\text{Δ} {E}^{\text{d}} {}_{\text{f}} = 0 ≡ 0.67$$

eV (taken from CZTS under Cu-poor conditions) and = 1 ≡ 1.54 eV (average of stannite- and wurtzite-CCdGSSe); (2) Eₕᵤₗₗ = 0≡0.073 eV per atom (from CZGSSe) and 1 = 0 eV per atom; and (3) E_{g} of 0 and 1 correspond to 0.60 eV and 0 eV deviations from the E^{HSE}_{g} of CZTS, where the DFT-HSE band gaps for CZTS,CZGS, CCdGSSe, and CZGSSe are plotted. FIG. 7 shows that the performance of CZTS (roughly the area of the triangle inscribed by the long dashed line) comes from its stability (Eₕᵤₗₗ = 0 eV per atom) and optimal band gap (E^{HSE}_{g} = 1.49 eV (ref. 143) ≈ E^{SQ}_{g}). However, CZTS is limited by the ease with which I_{sc}-reducing 2Cu_{Zn} + Sn_{Zn} defect clusters form

$$\left(\text{Δ} {E}^{\text{d}} {}_{\text{f}} = 0.67 \text{eV}\right) .$$

Complete Ge-substitution (CZGS, double-dotted dashed line), on the other hand, suppresses the formation of these detrimental defects

$$\left(\text{Δ} {E}^{\text{d}} {}_{\text{f}} = 0.92 \text{eV}\right) ,$$

leading to a performance increase along the

$$\text{Δ} {E}^{\text{d}} {}_{\text{f}}$$

axis, but widens the band gap (E^{HSE}_{g} = 2.09 eV) too far beyond that of the nearly optimal CZTS value. Partial selenization (CZGSSe, short dashed line) can be used to improve the band gap (E^{exp}_{g} = 1.65 eV) but it also reduces both the Ge-induced suppression of deep defects

$$\left(\text{Δ} {E}^{\text{d}} {}_{\text{f}} = 0.77 \text{eV}\right)$$

and the intrinsic stability of the material (Eₕᵤₗₗ = 0.073 eV per atom, ≈2.8 × k_{B}T at 298 K). Remarkably, complete Cd-substitution (CCdGSSe, dotted line) practically eliminates I_{sc}-decreasing 2+/4+ disorder

$$\left(\text{Δ} {E}^{\text{d}} {}_{\text{f}} = 1.54 \text{eV}\right) ,$$

optimizes the band gap (E_{g} = 1.45 eV), and effectively stabilizes the material (Eₕᵤₗₗ = 0.005 eV per atom < k_{B}T at 298 K, which is likely thermally accessible).

The stability of CCdGSSe is supported by reports of the synthesis and characterization of the closely related compounds Cu₂CdGeS₄ and Cu₂CdGeSe₄, which differ from CCdGSSe only in S—Se ratio. For both compounds, it is predicted that Eₕᵤₗₗ = 0 eV per atom, which is consistent with their synthesizability. Additionally, it is predicted that CCdGS and CCdGSe prefer the wurtzite and stannite polymorphs, respectively (see FIG. 4), which agrees with X-ray diffraction measurements.

The thermodynamics of CCdGSSe phase separation, i.e., Cu₂CdGeS₃Se → ¾Cu₂CdGeS₄ + ¼Cu₂CdGeSe₄, were also calculated. The configurational entropy of ideal S/Se mixing on the anion sublattice stabilizes CCdGSSe at temperatures above 133 K. Note that the 0 K convex hull at the composition of Cu₂CdGeS₃Se actually consists of Cu₂GeS₃ + CdSe and not the mixture of wurtzite-Cu₂CdGeS₄ and stannite-Cu₂CdGeSe₄. It was found that the S/Se mixing entropy and vibrational entropic contributions stabilize CCdGSSe with respect to the decomposition into Cu₂GeS₃ + CdSe at temperatures above 879 K, which is comparable with typical sulfurization temperatures of CZTS and CCdTS, i.e., 580–600° C. or 853-873 K.

The calculated band gap of CCdGSSe (1.45 eV) is bounded by the measured band gaps of CCdGS (1.85–2.05 eV) and CCdGSe (1.14–1.27 eV). Since the measured band gaps of quinary metal sulfide-selenides are proportional to x_{Se},-that of CCdGSSe should be approximately 1.67–1.86 eV, as found by linear interpolation. While this is slightly greater than the nearly ideal band gap of CZTS (1.49 eV), further selenization to Cu₂CdGeS₂Se₂ (x_{Se} = 0.5) optimizes the interpolated band gap (1.50–1.66 eV) and does not influence the conclusion that complete Cd- and Ge-substitution strongly suppresses the formation of detrimental defects.

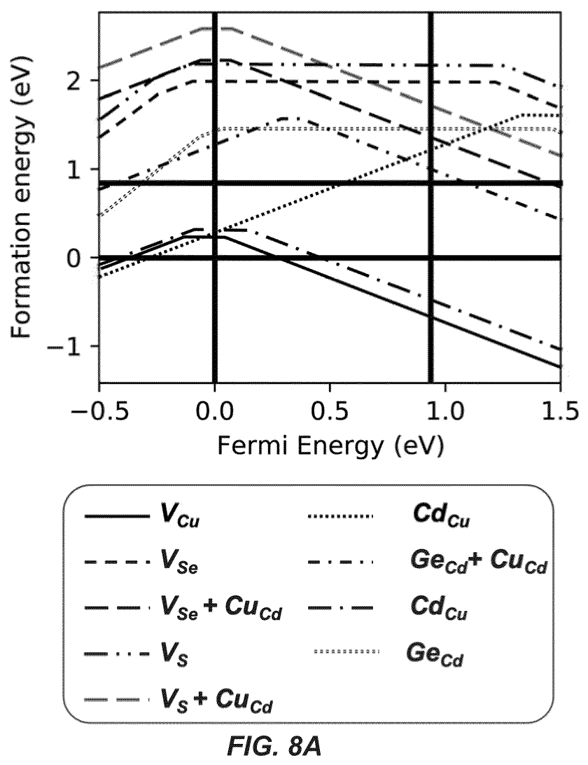

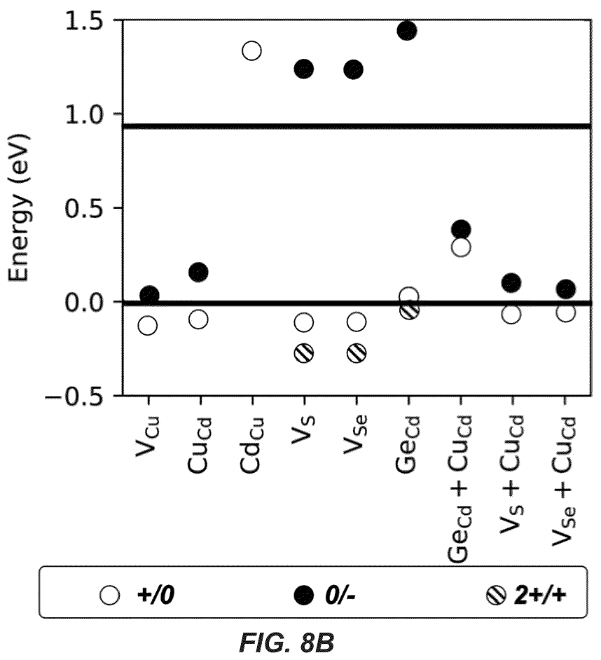

It also is crucial to know, for a given Fermi level, the most stable charge state and deep/shallow character of the defect and its potential trapping ability. The formation energies of the following charged defects and defect clusters in stannite CCdGSSe were calculated: V_{Cu}, Cu_{Cd}, Cd_{Cu}, V_{S}, V_{Se}, Ge_{Cd}, Vs + Cu_{Cd}, and V_{Se} + Cu_{Cd}. FIG. 8A shows that only V_{Cu} (q = –1, 0), Cu_{Cd} (q = –1, 0), and Cd_{Cu} (q = 1) should form in appreciable quantities for Fermi energies between the valence-band maximum (VBM) and conduction-band minimum (CBM), and under Cu-poor conditions (i.e., when CCdGS, Cd₄GeS₆, GeS₂, S, and Se are in equilibrium). The defect transition levels in FIG. 8B agree qualitatively with those for CZTSe, CZTS, CZGSe, and Ag₂ZnSnSe₄, with the exception of Ge_{Cd}, which exhibits deep donor levels within the valence band. The formation energy of Ge_{Cd} (1.44–1.45 eV), however, is well above that of the neutral 2Cu_{Zn} + Sn_{Zn} antisite cluster in CZTS (0.84 eV), which constitutes an upper bound on the formation energy of defects that affect solar cell parameters. Ge_{Cd} + Cu_{Cd} also has deep donor and acceptor levels, however, this defect can be discarded as well because of its high formation energy. Therefore, CCdGSSe should exhibit lower non-radiative recombination than CZTS.

The acceptor transition levels of V_{Cu} and Cu_{Cd} were at E_{F} – E_{VBM} = 39 meV and 146 meV, respectively. Therefore, V_{Cu} and Cu_{Cd} likely are present in detectable quantities for CCdGSSe but it is expected the absolute Cu_{X} concentrations to be lower than in CZTS (ΔE^{d}_{f} = –0.20 eV for Cu_{Zn} in CZTS versus 0.02 eV for Cu_{Cd} in CCdGSSe.

Table 3. DFT-SCAN formation energies under Cu-poor conditions of individual, neutral point defects (Cu_{X}, X_{Cu}, and Y_{X} where X and Y are the divalent and tetravalent elements, respectively) and charge-compensated defect clusters (Cu_{X}+X_{Cu} and 2Cu_{X}+Y_{X}) for CZTS (X = Zn, Y = Sn), CZGS (X = Zn, Y = Ge), and CCdGSSe (X = Cd, Y = Ge). “Cluster - ΣSeparate” is the stabilization of the cluster vs. the separate point defects. For all defects, the neutral, charge- compensated defect cluster is more stable than the sum of the individual neutral point defects.

| Material | X | Y | Formation Energy (eV) | | | | | Cluster –∑Separate (eV) | |
|---|---|---|---|---|---|---|---|---|---|
| | | | Cu_{X} | X_{Cu} | Y_{X} | Cu_{X}+X_{Cu} | 2Cu_{X}+Y_{X} | Cu_{X}+X_{Cu} | 2Cu_{X}+Y_{X} |
| CZTS | Zn | Sn | -0.20 | 1.34 | 1.85 | 0.22 | 0.67 | -0.92 | -0.78 |
| CZGS | Zn | Ge | -0.19 | 1.51 | 2.00 | 0.15 | 0.92 | -1.18 | -0.71 |
| CCdGSSe | Cd | Ge | 0.02 | 1.49 | 1.57 | 0.38 | 1.51 | -1.12 | -0.09 |

FIG. 8B also shows that only Cd_{Cu} has a donor transition level that is close to the conduction band but it is within the band itself. Therefore, one cannot assign the defects and/or defect complexes that were considered to the experimentally observed deep donor transition levels at ~50–120 meV below the CBM.

In addition to developing a feasible and original ion substitution scheme for optimizing kesterite solar cells, the mechanisms of defect suppression and promotion by Ge and Se were also clarified, emphasizing the crucial role of the inert pair effect and metal-chalcogen bond covalency, respectively.

These insights reveal three important materials design considerations for tuning defect formation in kesterite-type absorbers via ion substitution: (1) bond order (BO) conservation, (2) cation redox inactivity, and (3) anion polarizability. The BO conservation principle states that the sum of the strengths of the bonds to an anion from its adjacent cations is nearly equal to its valence.

(1) BO Conservation: If some of the anion-cation bonds become stronger, e.g., upon cation substitution, then the others must become weaker to conserve the BO of the anion. By replacing Sn with an element that forms stronger bonds with S, such as Ge (BDE = 5.54 ± 0.03 eV for Ge—S vs. 4.84 eV for Sn—S), BO conservation dictates that the Cu—S bonds must become weaker; therefore, Cu vacancies should form more easily in CZGS than CZTS, as is shown in FIG. 2B (ΔE_{d}^{f} = –0.02 eV for CZGS vs. 0.17 eV for CZTS). (2) Cation Redox Inactivity: While Zn exhibits only one normal oxidation state (2+), Cu and Sn exhibit two (1+ and 2+ for Cu and 2+ and 4+ for Sn), where Sn²⁺ is stabilized by the inert pair effect. The redox activities of Cu and Sn promote the formation of Cu_{Zn} and Sn_{Zn} antisites, respectively, because they both can adopt the 2+ oxidation state of Zn, thereby reducing the electrostatic energy penalty associated with the formation of these antisites and, consequently, their clusters. (3) Anion Polarizability: Despite the fact that 2Cu_{Zn} + Y_{Zn} is neutral and globally charge compensated, the generated charge carriers are, to some extent, delocalized. Given that Se (3.89 × 10–24 cm³) is more polarizable than S (2.87 × 10–24 cm³), it should be able to stabilize this detrimental defect, which is precisely what was found, where the formation energy of 2Cu_{Zn} + Ge_{Zn} decreases almost linearly with increasing x_{Se}.

These materials and layers can be fabricated using various known techniques. For example, by dissolving an appropriate quantity of copper acetate hydrate, cadmium acetate dihydrate, and germanium tetrachloride in 2-methoxyethanol, spin-coating the solution onto a Mo-glass substrate at ≈4000 rpm, and then annealing first at 280° C. to remove excess solvent and then at ≈580-600° C. under sulfurization and selenization conditions, as appropriate, in order to achieve the desired Se/S levels and thin-film quality.

A second aspect of the present disclosure are thin-film solar cells using Cu₂CdGe(S,Se)₄ solar cell absorbers. Inter alia, the disclosed approach improves the performance of kesterite-based solar cells by suppressing the formation of detrimental defects, promoting the formation of beneficial defects, and optimizing the band gap.

The disclosed chalcogenide can be used in any thin-film solar cell that employs a kesterite-based absorber. The chalcogenide should improve the solar cell efficiency by suppressing the formation of bandgap-fluctuation- and recombination-inducing defects compared to the state-of-the-art (SOA).

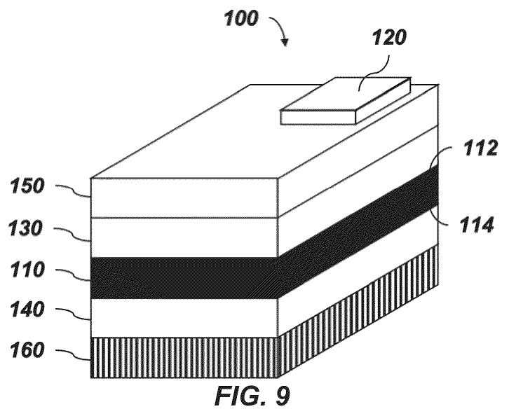

Referring to FIG. 9, generally, the disclosed thin-film solar cells (100) comprise an absorber layer (110), where the absorber layer comprises a composition of matter having the formula Cu₂CdGe(SₓSe₁₋ₓ)₄, where 0 < x < 1.

A plurality of additional layers may also present, including up to two contact layers, a buffer layer, a conductive glass layer, and/or a substrate layer.

In a preferred embodiment, the solar cell (100) consists of the absorber layer (110), a first contact layer (120) and a second contact layer (140). The two contact layers (120, 140) sandwich the absorber layer (110). Said differently, the absorber layer (110) has a first surface (112) that faces the first contact layer (120), and a second surface (114) opposite that of the first surface (112), where the second surface (114) faces the second contact layer (140).

The first and second contact layers may be comprised of any appropriate materials.

The first contact layer preferably comprises silver. In a preferred embodiment, the first contact layer comprises a silver paste. In some embodiments, the first contact layer is silver nanowires (AgNW). In some embodiments, the first contact layer is patterned so as to cover only a portion of the underlying layers. That is, when viewing the solar cell from above, the first contact layer has a 2D area defined by the first contact layer’s width and height that is smaller than a 2D area defined the width and height of one or more underlying layers.

The second contact layer is preferably comprised of Mo.

One or more layers may be between the first contact layer (120) and the absorber layer (110). In some embodiments, two layers are between the first contact layer and the absorber layer: a buffer layer (130) and a conductive glass layer (150).

The buffer layer (130) should be in contact with the absorber layer, and the window layer (if present) will be in contact with the buffer layer and the first contact layer. The buffer layer should be, e.g., an n-type buffer layer for band alignment.

The conductive glass and buffer layers may be any appropriate materials as known to those of skill in the art.

In preferred embodiments, the conductive glass layer comprises or consists of a transparent conducting oxide, such as fluorine-doped tin oxide (FTO), indium tin oxide (ITO). In some embodiments, the first contact layer consists of SnₓIn₂₋ₓO₃; optionally 0.7 ≤ x ≤ 0.8.

In preferred embodiments, the buffer layer is CdS.

In preferred embodiments, no window layer is present, and the thin film solar cell (100) consists or consists essentially of a first contact layer (120), a buffer layer (130) in contact with the first contact layer, the absorber layer (110) in contact with the buffer layer, a second contact layer (140) in contact with the absorber layer, and optionally a substrate layer (160).

The substrate layer may be comprised of any appropriate substrate material. In preferred embodiments, the substrate layer is comprised of glass.

While additional layers may be present, in a preferred embodiment, the solar cell consists of all of the disclosed layers – (1) a first contact layer (120) (e.g., silver paste), (2) a conductive glass layer (150) (e.g., ITO) in contact with the first contact layer, (3) a buffer layer (130) (e.g., CdS) in contact with the conductive glass layer, (4) an absorber layer (110) (e.g., CCdGSSe) in contact with the buffer layer, a second contact layer (140) (e.g., Mo) in contact with the absorber layer, and a substrate (160) (e.g., glass) in contact with the second contact layer.

Those skilled in the art will recognize or be able to ascertain using no more than routine experimentation many equivalents to the specific embodiments of the invention described herein. Such equivalents are intended to be encompassed by the following claims.

What is claimed:

1. A composition of matter having the formula Cu₂CdGe(SₓSe₁₋ₓ)₄, where 0 < x < 1.

2. The composition of matter according to claim 1, wherein the composition has adopted a stannite or wurtzite crystal structure.

3. The composition of matter according to claim 1, wherein x is between 0.1 and 0.9.

4. The composition of matter according to claim 1, wherein x is between 0.7 and 0.8.

5. The composition of matter according to claim 1, wherein the composition is configured to have a band gap of between 1.4 eV and 1.5 eV.

6. A solar cell, comprising:
an absorber layer comprising a composition of matter having the formula Cu₂CdGe(SₓSe₁₋ₓ)₄, where 0 < x < 1.

7. The solar cell according to claim 6, further comprising:
a first contact layer and a second contact layer, the second contact layer being in contact with the absorber layer, the absorber layer being between the first contact layer and the second contact layer; and
a buffer layer between the absorber layer and the first contact layer.

8. The solar cell according to claim 7, wherein the buffer layer comprises CdS.

9. The solar cell according to claim 7, further comprising a window layer between the first contact layer and the absorber layer.

10. The solar cell according to claim 8, wherein the window layer comprises ZnO.

11. The solar cell according to claim 7, further comprising a substrate layer, the substrate layer being in contact with the second contact layer.

12. The solar cell according to claim 11, wherein the substrate layer is glass.

13. The solar cell according to claim 7, wherein the first contact layer comprises a transparent conducting oxide.

14. The solar cell according to claim 9, wherein the transparent conducting oxide is SnₓIn₂₋ₓO₃.

15. The solar cell according to claim 7, wherein the second contact layer comprises Mo.
